(19) United States
(12) Patent Application Publication
(10) Pub. No.: US 2004/0074533 A1
(43) Pub. Date: Apr. 22, 2004

(54) Superconductor-semiconductor solar cells and light detectors

(76) Inventor: Hongjun Pan, Knoxville, TN (US)

Correspondence Address: Hongjun Pan, 1929 Dunraven Drive, Knoxville, TN, 37922, US

(21) Appl. No.: 10/274,746

(22) Filed: Oct. 21, 2002

(51) Int. Cl. H01L 31/00

(52) U.S. Cl. 136/255

(57) ABSTRACT

A new type of solar cells and light detectors are proposed by depositing high Tc black, ceramic type superconductor on a clean surface of a p-type or n-type semiconductor. A Schottky barrier is formed at the interface of the two materials. In a preferred embodiment, the superconductor is YBa₂Cu₃O_{7-L} and the semiconductor is any one of the p-type Si, n-type Si, p-type GaAs and n-type GaAs. This type of solar cells will potentially have much higher solar energy conversion efficiency than conventional solar cells due to the strong and very wide absorption range of light frequencies. This type of light detectors will have much higher detection sensitivity than conventional light detectors.

### BACKGROUND OF THE INVENTION

1. Field of the Invention

This invention is in the field of solar cells and light detectors

2. Description of the Prior Art

There are two types of solar cells. The first type of solar cells is based on semiconductor p-n junction; the commonly used semiconductors are doped Si and GaAs. The Si and GaAs have low light absorption efficiency and narrow absorption band width, such solar cells have low solar energy conversion efficiency and their cost is high, can not be used in large scale.

The second type of solar cells is based on the metal-semiconductor Schottky barrier. In 1984 and 1980, two patents were granted by U. S PTO to the solar cells based on Schottky barrier (U.S. Pat. Nos. 4,427,840 and 4,227,943). In patent 4427840, a layer of Mg is deposited on a layer of p-type polyacetylene to form the Schottky barrier at the interface of the two layers. Sun light can be converted to electricity in this device. In U.S. Pat. No. 4,227,943, the solar cell is constructed by coating an n-type semiconductor GaAs on a thin layer of bromine doped, polymeric sulfur-nitride, and Schottky barrier is formed at

The FIG. 3A shows the energy levels 19 and 20 of the superconductor 2 and the p-type semiconductor 3 at the time they just contact each other. The Fermi level 20 of the semiconductor 3 is much lower than the Fermi level 9 of the superconductor 2. The electrons in the superconductor 2 move to the semiconductor 3. The energy level 20 of the semiconductor 3 increases. The electron transfer stops when the Fermi levels 19 and 20 are equal shown in FIG. 3B. The superconductor side is positively charged and the semiconductor is negatively charged, therefore, the Schottky barrier 21 is formed which stops the electron further transfer. The performance of solar cells and light detectors depends on the Schottky barrier and the efficiency of light absorption.

For the superconductor-n-type semiconductor Schottky barrier (not shown), it is formed in just opposite way to FIG. 3. The Fermi level of the n-type semiconductor is higher than the Fermi level of superconductor. The electrons move from n-type semiconductor to superconductor, and the Fermi level of the semiconductor decreases unitl the two Fermi levels are equal. The n-type semiconductor is positively charged and superconductor is negatively charged.

FIG. 4 illustrates how this solar cell works and why it has high energy conversion efficiency. The light 6 hits the semiconductor 3 and a small portion of the light is absorbed by the semiconductor 3 near the interface 7 of the semiconductor side, electron-hole pairs are generated and separated by the Schottky barrier. The electrons are swept by the Schottky barrier to the superconductor 2 side and the holes are swept to the semiconductor 3 side, therefore electricity is produced. The semiconductor 3 only absorbs a small portion of the light 6 due to its narrow absorption frequency range of light. In conventional solar cells, the main portion of incoming light are not absorbed and wasted. In the solar cell of this invention, the light 9 which is not absorbed by the semiconductor 3 is absorbed by the interface 8 of the black superconductor 2 side, and the energy of the light absorbed in this region excites more electrons and produces more electricity, therefore, this solar cell uses most of the energy of the sun light and have much higher energy conversion efficiency than the conventional solar cells. the interface of the two layers. These two solar cells have low energy conversion efficiency also due to their low absorption efficiency, narrow absorption bandwidth.

A solar cell with a higher energy conversion efficiency and low cost is highly demanded, especially when the natural resource of reserved energy (petroleum, coal) are quickly depleting.

The high transition temperature (Tc) superconducting compound YBa₂Cu₃O_{7-δ} as several special properties. 1. It is metallic at room temperature and a good conductor. 2. It turns to a superconductor at about 90 K so no any resistance below that temperature. 3. It is black, has strong absorption for all frequencies of visible light range, it is also has strong absorption in Infrared and far Infrared range. No other materials used for solar cells so far have such wide range and high efficiency of light absorption. 4. It has good optical conductivity for wide range of light frequency covering from visible light to far infrared, specially in the far infrared range the optical conductivity is very strong. In summary, YBa₂Cu₃O_{7-δ} is the ideal choose for constructing solar cells and light detectors. The solar cells made of such material will have much higher energy conversion efficiency and a light detectors made of such materials will have very good sensitivity. To the best knowledge of this inventor, no such solar cells and light detectors with the same construction of this invention has been invented or proposed so far.

### SUMMARY OF THE INVENTION

It is an object of the invention to provide an efficient solar cell

It is an object of the invention to provide a low cost solar cell

It is an object of the invention to provide an efficient light detector

It is an object of the invention to provide a low cost light detector

The solar cell constructed by depositing high Tc black, ceramic type superconductor such as YBa₂Cu₃O_{7-δ} on the clean surface of any one of semiconductor wafer such as p-type Si, n-type of Si, p-type GaAs and n-type GaAs.

A light detector is constructed in the similar way.

### BREIF DESCRIPTION OF THE DRAWINGS

FIG. 1 is the cross section view of the solar cell.

FIG. 2 is the cross section view of the light detector.

FIG. 3 illustrates the formation of Schottky barrier.

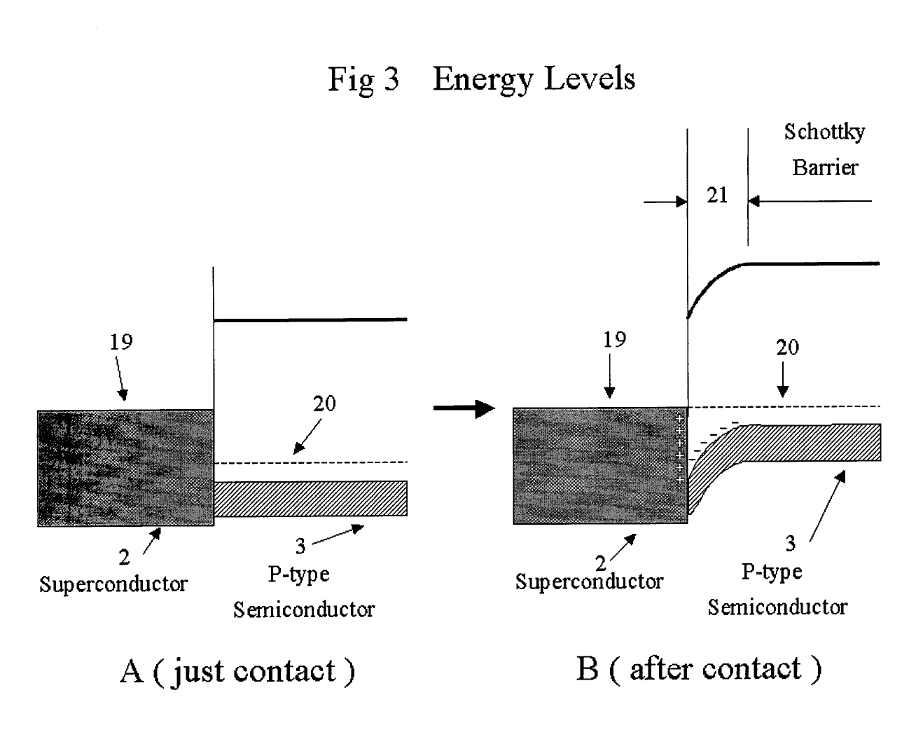

FIG. 4 illustrates how this solar cell (light detector) works and why it has high energy conversion efficiency.

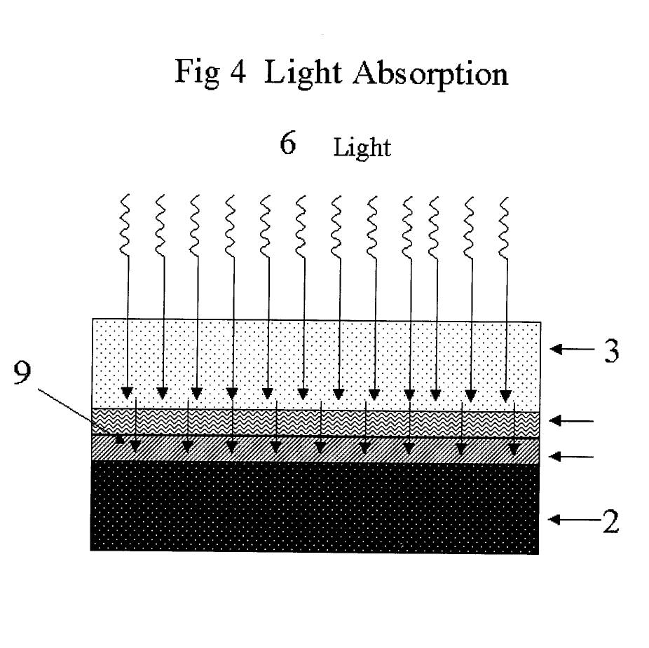

### DESCRIPTION OF THE PREFERRED EMBODIMENT

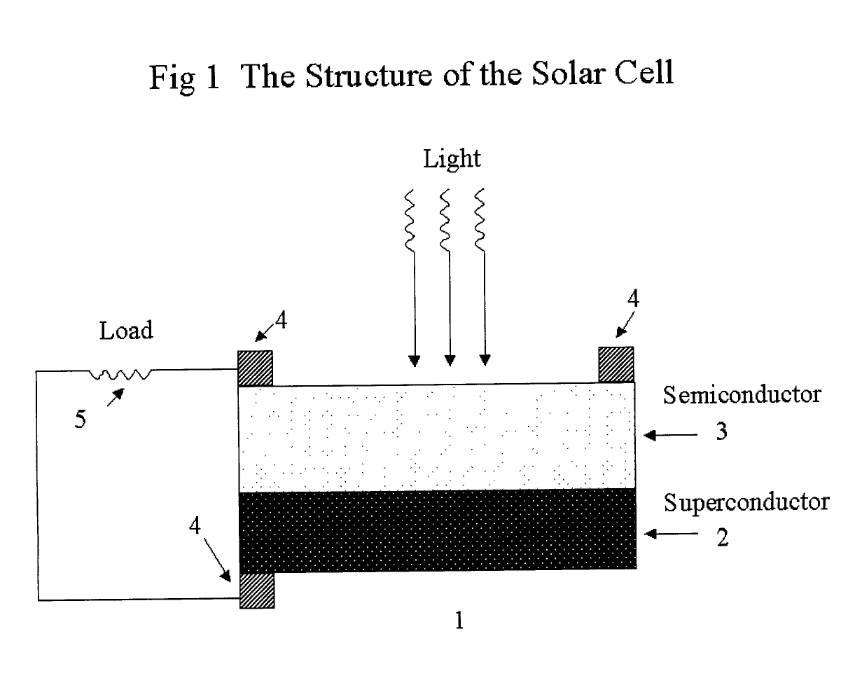

FIG. 1 displays the construction of the solar cell. The solar cell 1 is constructed by depositing high Tc black ceramic type superconductor YBa₂Cu₃O_{7-δ}2 on the clean surface of a semiconductor wafer 3, the semiconductor can be any one of p-type Si, ntype Si, p-type GaAs and n-type GaAs. The depositing superconductor YBa₂Cu₃O_{7-δ} can be conducted by either chemical vapor deposition or other means. Conducting metal such as gold, cupper or aluminum is coated on the outer surface of the semiconductor wafer 3 and outer surface of superconductor 2 to form ohmic contact 4 for electric power output. Sun light hits the surface of the semiconductor 3, is absorbed by the semiconductor 3 and the superconductor 2 to generate electricity. The electric power generated by the solar cell 1 is sent to a load 5 through the metal ohmic contact 4.

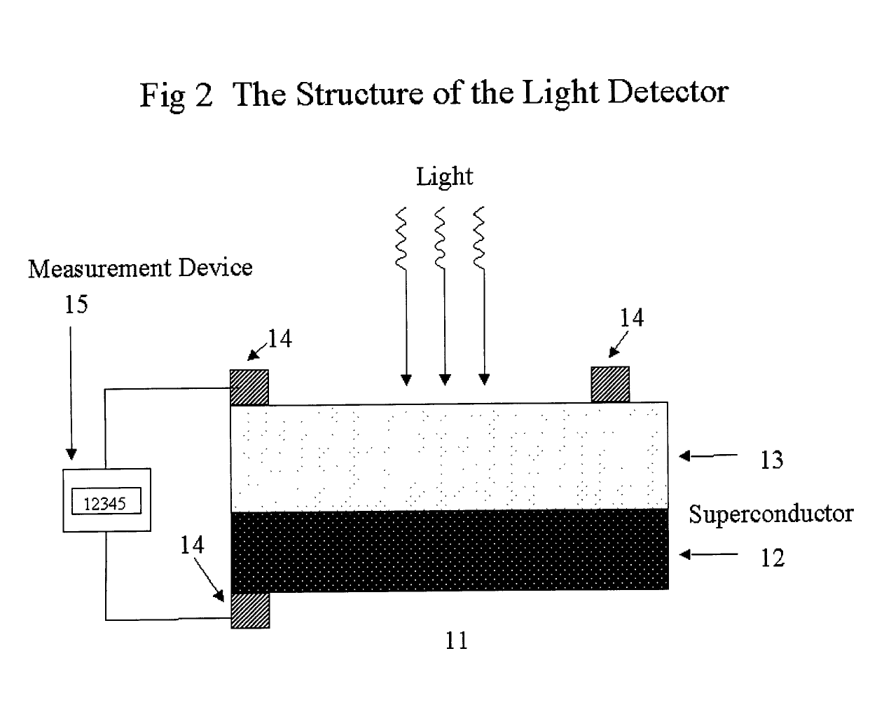

FIG. 2 shows the construction of the light detector. The light detector 11 is constructed by depositing high Tc black ceramic type superconductor YBa₂Cu₃O_{7-δ} 12 on the clean surface of a semiconductor wafer 13, the semiconductor 13 can be any one of p-type Si, n-type Si, p-type GaAs and n-type GaAs. The depositing superconductor YBa₂Cu₃O_{7-δ} can be conducted by either chemical vapor deposition or other means. Conducting metal such as gold, cupper or aluminum is coated on the outer surface of the semiconductor wafer 13 and outer surface of superconductor 12 to form ohmic contact 14 for electric signal output. The light hits the surface of the semiconductor 13, is absorbed by the semiconductor 13 and the superconductor 12 to generate electricity. The electric signal generated by the light detector 11 is measured by a measurement device 15 through the metal ohmic contact 14.

### REFERENCES

U.S. Pat. No. 4,427,840, December, 1981. Waldrop et al. Class 136/255

U.S. Pat. No. 4,227,943, June, 1979 Cohen et al. Class 136/255

The same construction can be used as a light detector. The light is absorbed by the detector and produce electrical signal, the electric signal is very sensitive to the amount of the light and can be measured by a measurement device.

The invention is applicable for solar cells and light detectors made of superconductors and semiconductors other than YBa₂Cu₃O_{7-δ} and Si, GaAs, and numeric variations and modifications can be made without departing from the scope of the present invention. Accordingly, it should be clearly understood that the form of the invention described above and shown in the accompanying drawings is illustrative only and is not intended to limit the scope of the invention.

What is claimed is:

1. A solar cell comprising a high Tc superconductor and a semiconductor to form a Schottky barrier.

2. The cell of claim 1 wherein said superconductor is black and ceramic type superconductor

3. The cell of claim 1 wherein said superconductor is YBa₂Cu₃O_{7-δ}.

4. The cell of claim 1 wherein said semiconductor is any one of p-type Si, n-type Si, p-type GaAs and n-type GaAs.

5. The cell of the claim 1 wherein said superconductor is a film deposited on the said semiconductor.

6. A light detector comprising a high Tc superconductor and a semiconductor to form a Schottky barrier.

7. The detector of claim 6 wherein said superconductor is black and ceramic type superconductor

8. The detector of claim 6 wherein said superconductor is YBa₂Cu₃O_{7-δ}.

9. The detector of claim 6 wherein said semiconductor is any one of p-type Si, n-type Si, p-type GaAs and n-type GaAs.

10. The detector of the claim 6 wherein said superconductor is a film deposited on the said semiconductor.
